(19) United States
(12) Patent Application Publication
(10) Pub. No.: US 2006/0281228 A1
(43) Pub. Date: Dec. 14, 2006

(54) Lead-frame type semiconductor package and lead frame thereof

(75) Inventors: Chien-Tang Li, Taichung (TW); Chung-Hsien Yang, Taichung (TW); M. C. Lin, Taichung (TW)

Correspondence Address: BIRCH STEWART KOLASCH & BIRCH, PO BOX 747, FALLS CHURCH, VA, 22040-0747, US

(73) Assignee: Siliconware Precision Industries Co., Ltd., Taichung Hsien (TW)

(21) Appl. No.: 11/439,250

(22) Filed: May 24, 2006

(30) Foreign Application Priority Data
May 24, 2005 (TW) 094116831

(51) Int. Cl. H01L 21/00; H01L 23/02

(52) U.S. Cl. 438/123; 257/678

(57) ABSTRACT

A lead-frame type semiconductor package is provided, including: a lead frame having a plurality of long leads and short leads, wherein a chip-attaching area is defined on the plurality of long leads, and at least a portion of each of the long leads within the chip-attaching area is formed with a recess; a chip mounted on the chip-attaching area and covering the recesses; a plurality of bonding wires for electrically connecting the chip to the corresponding long leads and short leads around the chip; and an encapsulant for encapsulating the chip, the plurality of bonding wires, a portion of the long leads and a portion of the short leads, wherein the encapsulant is filled into the recesses and gaps between the long leads, so as to solve a problem of incomplete filling in a conventional package.

### FIELD OF THE INVENTION

The present invention relates to lead-frame type semiconductor packages and lead frames thereof, and more particularly, to a lead-frame type semiconductor package without a die pad and a lead frame thereof.

### BACKGROUND OF THE INVENTION

A Thin Small Outline Package (TSOP) is a well-developed packaging technique, as shown in FIG. 1, wherein a semiconductor chip 50 is provided on a lead frame 52 having a plurality of leads 51 on both edges, and an encapsulant 53 is used to cover the chip 50 and a plurality of bonding wires so that the leads 51 exposed from both edges could be electrically connected.

In order to provide a more convenient way for the chip to be electrically connected to the leads, and enhance electrical property, performance and quality, the packaging technique may be further modified to form a Chip on Lead Thin Small Outline Package (COL TSOP) by mounting the chip on the adjacent leads directly. For instance, as shown in FIGS. 2A and 2B, such an improved package disclosed in U.S. Pat. No. 5,780,925, is fabricated by the aforementioned COL TSOP packaging technique, comprising the steps of preparing a lead frame 60 without a die pad, wherein the lead frame 60 comprises a plurality of correspondingly aligned long leads 61 and short leads 62; adhering a chip 63 on the extended long leads 61; and performing packaging processes.

However, this type of package may generate a serious quality issue during molding process and decrease its structural reliability dramatically. As the long leads 61 of the COL TSOP structure are extended perpendicularly to the direction of mold flow (as shown in FIG. 3), to completely fill the gaps between the long leads 61 with the mold flow of encapsulant can be hardly achieved. It is even more difficult to make the mold flow flowing into regions such as the gap spaces between the long leads 61 underlying the chip 63. Thus, after the molding process is completed, a plurality of unfilled voids 64 (or voids 64 with incomplete fillings) are generated between the gap spaces of the long leads 61, which may cause a popcorn phenomenon easily and lead to cracks in the encapsulant and deformation of the entire package structure, if the structure is heated during subsequent high-temperature fabricating processes.

A package structure proposed by U.S. Pat. No. 6,753,206 is also subject to the foregoing type of package, as shown in FIG. 4, wherein the upper surfaces and lower surfaces of long leads 70 are stacked with chips 71. A nonconductive adhesive is employed to be filled between each of the long leads 70 in this conventional technique, however voids with incomplete fillings (or unfilled voids) may still be generated as a result of improper control of adhesive injection, while injecting adhesives into the tiny gap spaces. Accordingly, conventional technique as such also has the same problem in fabricating a structure with good quality, as discussed above.

In a lead frame without a die pad, a the chip may be disposed on the long leads to facilitate electrical connection; however, if the problem of being unable to fill the gap spaces between each of the long leads completely with the encapsulant flow during molding process cannot be solved, such technique may not be feasible for mass production or product commercialization, and the advantage of its electrical design may not be maximized.

Accordingly, a need still remains for providing a lead-frame type semiconductor package and a lead frame thereof, which allow gap spaces between each of the leads and the chip to be completely filled with encapsulant flow.

Solutions to these problems have been long sought but prior developments have not taught or suggested any solutions and, thus, solutions to these problems have long eluded those skilled in the art.

### SUMMARY OF THE INVENTION

In light of the drawbacks of the above prior arts, the primary objective of the present invention is to provide a lead-frame type semiconductor package and a lead frame thereof, which can allow an encapsulant flow to be filled into every gap space inside the lead frame.

Another objective of the present invention is to provide a lead-frame type semiconductor package and a lead frame thereof, which can prevent voids from forming between leads during molding.

A further objective of the present invention is to provide a lead-frame type semiconductor package and a lead frame thereof, which are provided with high reliability.

And yet another objective of the present invention is to provide a lead-frame type semiconductor package and a lead frame thereof, which can allow an encapsulant flow to flow smoothly during molding.

In accordance with the above and other objectives, the present invention provides a lead-frame type semiconductor package, comprising a lead frame having a plurality of long leads and short leads, wherein a chip-attaching area is predetermined on the long leads, and at least a portion of each of the long leads within the chip-attaching area is formed with a recess; a chip mounted on the chip-attaching area and covering the recesses; a plurality of bonding wires for electrically connecting the chip to the corresponding long and short leads surrounding the chip; and an encapsulant for encapsulating the chip, the bonding wires, at least a portion of the long leads and at least a portion of the short leads, wherein the encapsulant is filled into the recesses.

The lead frame of the present invention comprises: a lead frame body; a plurality of short leads connected to the lead frame body; and a plurality of long leads connected to the lead frame body and having a chip-attaching area predetermined thereon, wherein at least a portion of each of the long leads within the chip-attaching area is formed with a recess.

A plurality of the foregoing recesses may be formed with flow passages for the encapsulant flow to be flowed into the gap spaces between the long leads via the recesses, such the gap spaces are filled with the encapsulant. Further, as the recesses are formed by half-etching process, a width of each recess is smaller than a width of the chip-attaching area, and a depth of each recess is preferably half a thickness of each long lead.

Thus, by the design of the present invention having the long leads formed with the recesses, the prior-art problem that the encapsulant flow cannot be filled into the gaps between the long leads can be solved, such that strength of the package structure can be enhanced and reliability of package can be improved.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 (PRIOR ART) is a schematic section view of a conventional Thin Small Outline Package (TSOP);

FIG. 2A (PRIOR ART) is a schematic top elevation view of a conventional Chip on Lead Thin Small Outline Package (COL TSOP);

FIG. 2B (PRIOR ART) is a schematic cross-sectional view of a conventional Chip on Lead Thin Small Outline Package (COL TSOP);

FIG. 3 (PRIOR ART) is a schematic top elevation view showing voids appearing in the conventional package of FIG. 2A and FIG. 2B, after molding process;

FIG. 4 (PRIOR ART) is a schematic cross-sectional view of a conventional package disclosed by U.S. Pat. No. 6,753,206;

FIG. 5A is a schematic top elevation view of the lead frame in accordance with a preferred embodiment of the present invention;

FIG. 5B is a schematic cross-sectional view of a lead frame in accordance with a preferred embodiment of the present invention;

FIG. 6A is a schematic top elevation view of the lead-frame type semiconductor package in accordance with a preferred embodiment of the present invention;

FIG. 6B is a schematic cross-sectional view of a lead-frame type semiconductor package in accordance with a preferred embodiment of the present invention; and

FIG. 7 is a schematic cross-sectional view of a lead-frame type semiconductor package in accordance with another embodiment of the present invention.

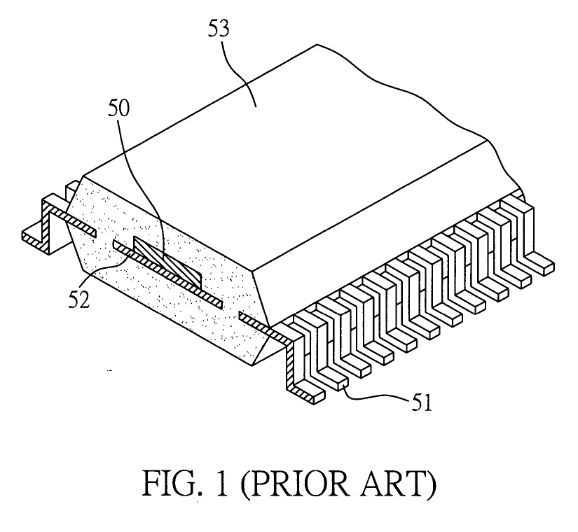

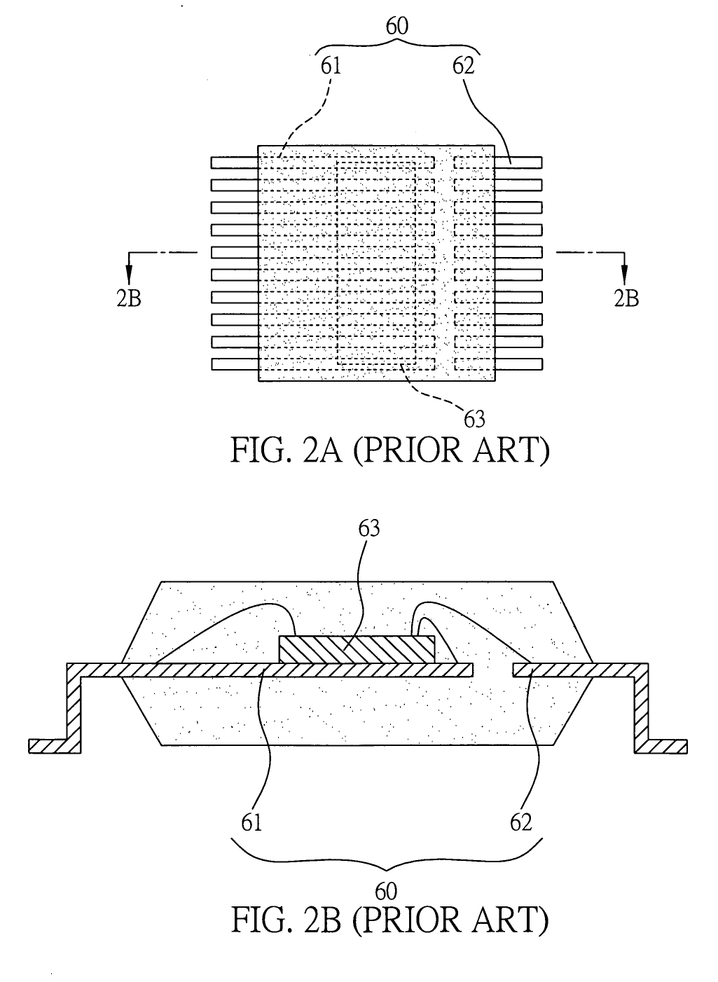

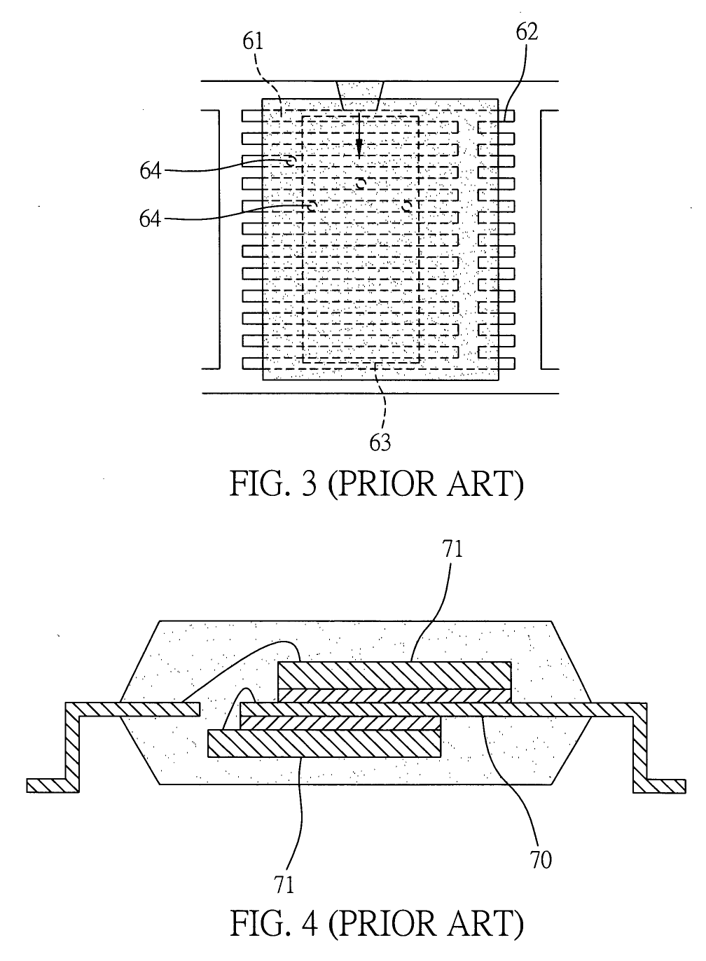

### DETAILED DESCRIPTION OF THE PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing FIGS. Similarly, although the views in the drawings for ease of description generally show similar orientations, this depiction in the FIGS. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

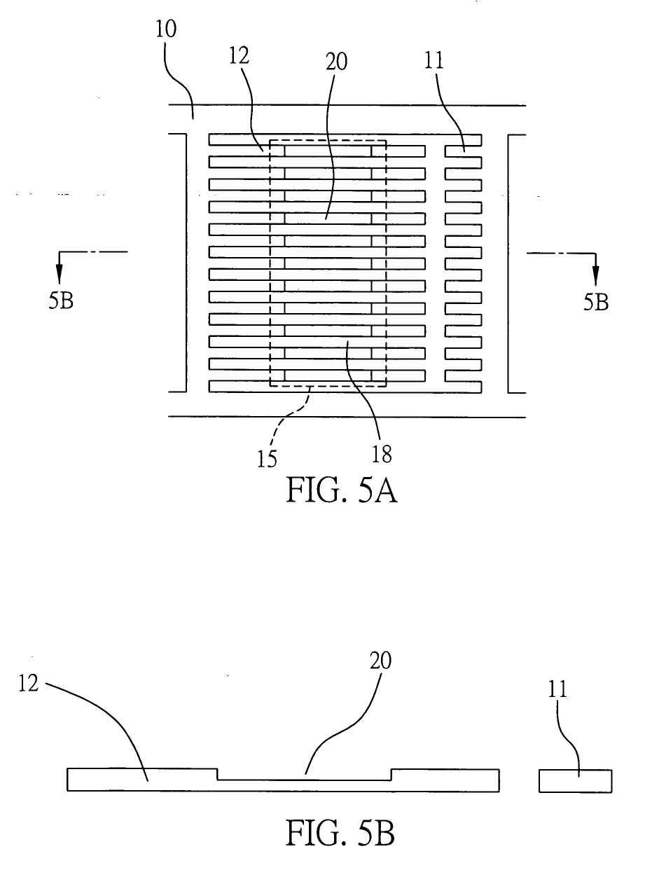

The present invention proposes a lead-frame type semiconductor package. As shown in FIGS. 5A and 5B, a lead frame of a lead-frame type semiconductor package according to an embodiment of the present invention comprises a rectangular lead frame body 10; a plurality of short leads 11 connected to the lead frame body 10; and a plurality of long leads 12 connected to the lead frame body 10, each of the long leads 12 being aligned with and corresponded to each of the short leads 11, wherein a chip-attaching area 15 (i.e. dash-line area) is predetermined on the long leads 12, and at least a portion of each of the long leads 12 within the chip-attaching area 15 is formed with a recess 20, such that a recessed area is formed at the central region of the long leads 12.

In one embodiment, the plurality of recesses 20 are formed by half-etching process, wherein a width of each of the recesses 20 is smaller than a width of the chip-attaching area 15, and a depth of each of the recesses 20 is preferably half a thickness of each of the long leads 12. Therefore, a rectangular area formed by the recesses 20, which is slightly smaller than the chip-attaching area 15, may be covered by the chip 25, after the chip 25 is mounted thereon, such that flow passages for the mold flow of an encapsulant 30 may be formed during subsequent molding process, so as to allow the encapsulant 30 flow to be flowed into gap spaces 18 between the long leads 12 via the recesses 20, such that the gap spaces 18 may be filled with the encapsulant 30.

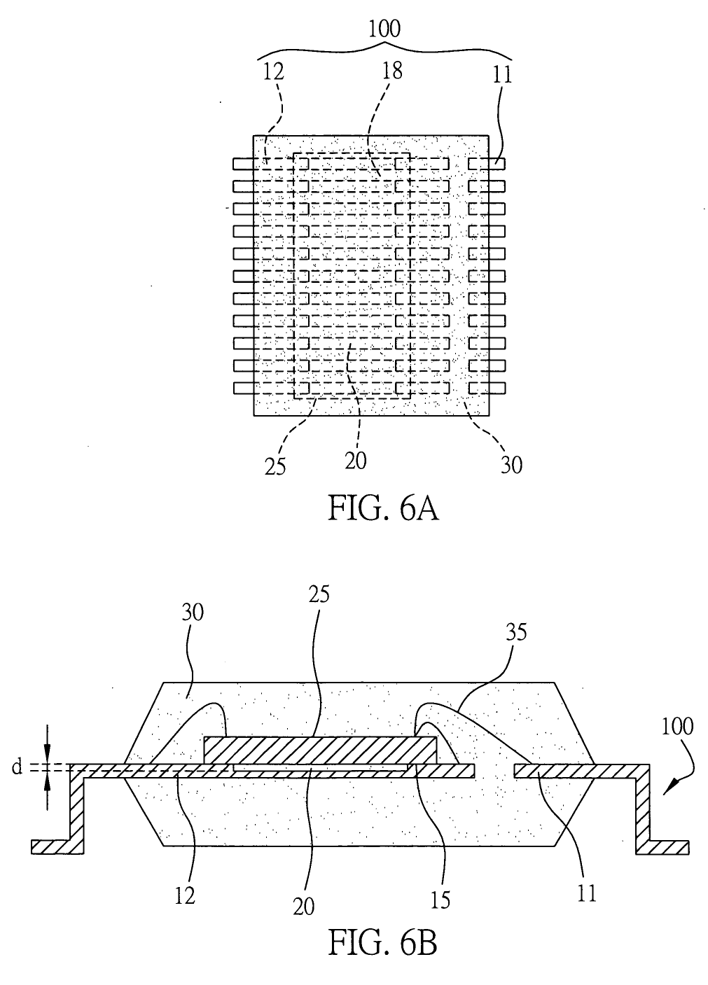

Furthermore, as shown in FIGS. 6A and 6B, a lead-frame type semiconductor package in accordance with a preferred embodiment of the present invention comprises a lead frame 100 having a plurality of long leads 12 and a plurality of short leads 11, wherein each of the long leads 12 is aligned with and corresponded to each of the short leads 11, a chip-attaching area 15 is predetermined on the long leads 12, and at least a portion of each of the long leads 12 within the chip-attaching area 15 is formed with a recess 20.

A plurality of recesses 20 are formed by half-etching process, however the shapes and sizes thereof may vary and should not be limited to that described and illustrated. In the preferred embodiment, the width of each of the recesses 20 is smaller than the width of the chip-attaching area 15, and the depth of each of the recesses 20 is preferably half the thickness of each of the long leads 12. Thus, the rectangular area formed by the recesses 20 is slightly smaller than the chip-attaching area 15.

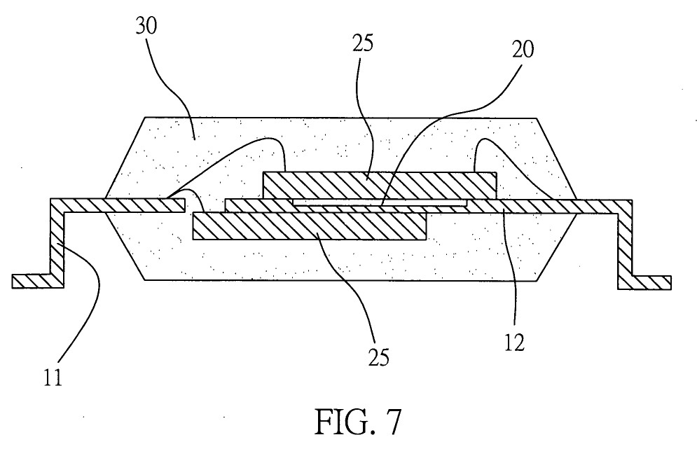

As shown in FIGS. 6B and 7, a chip 25 is disposed on the long leads 12, wherein the chip 25 is mounted on the chip-attaching area 15 and covering the recesses 20. At this stage, at least a gap d (as shown in FIG. 6B) is formed between a top surface of each of the recesses 20 and a bottom surface of the chip 25, wherein a plurality of gap d may be formed and used to form flow passages for an encapsulant 30 flow during subsequent molding, so as to allow the encapsulant 30 flow to be flowed into the gap spaces 18 between the long leads 12 via the recesses 20, such that such the gap spaces are filled with the encapsulant 30.

The package further includes a plurality of bonding wires 35, wherein the bonding wires 35 are gold wires, for being electrically connected respectively to at least a connection pad (not shown) on the chip 25 and the surrounded corresponding long leads 12 and/or short leads 11. Thus, signals from the chip 25 can be transferred to the opposite edges of long leads 12 and short leads 11 (i.e. the long leads 12 are located at one edge, and the short leads 11 are located at the other edge), such that the signal can be transferred to an external electronic device such as a printed circuit board.

Last, the package further comprises an encapsulant 30 for encapsulating the chip 25, the plurality of bonding wires 35, a portion of the long leads 12 and a portion of the short leads 11. During the molding process, the encapsulant 30 can flow into the recesses 20 and fill the gap spaces 18 between the long leads 12 via the flow passages between the chip 25 and the recesses 20, such that the gap spaces 18 can be completely filled to prevent voids from forming, thereby solving drawbacks of the prior arts.

The present invention can be applied to a multi-chip structure as well. For example, another embodiment, as shown in FIG. 7, depicts that the chips 25 may be disposed on both upper and lower surfaces of the long leads 12, wherein each of the long leads 12 is etched to form a recesses 20 at a region covered by the chip 25 to serve as a flow passage for the encapsulant 30 flow to be flowed into the gap spaces, such that the spaces can be filled by the encapsulant 30, thereby solving prior-art problems.

Accordingly, the present invention is characterized in that the surfaces of the long leads underlying the chip are etched to form recesses according to the direction of a mold flow, and the gap spaces between the long leads are filled with the encapsulant flow via the flow passages formed by the recesses. It should be noted that the size, shape, quantity, and arrangement of the recessed long leads are not limited to that described and illustrated in the present invention, and may be modified according to different structures and sizes of packages.

Thus, by the design of the present invention having the long leads formed with the recesses, the prior-art drawback that the encapsulant flow cannot be filled into the gaps between the long leads can be solved, such that strength of the package structure can be enhanced and reliability of package can be improved.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A lead-frame type semiconductor package comprising:
a lead frame having a plurality of long leads and short leads, wherein a chip-attaching area is predetermined on the long leads, and at least a portion of each of the long leads within the chip-attaching area is formed with a recess;
at least a chip mounted on the chip-attaching area and covering the recesses;
a plurality of bonding wires for electrically connecting at least a connection pad of the chip to the corresponding long leads and short leads surrounding the chip; and
an encapsulant for encapsulating the chip, the bonding wires, a least a portion of the long leads and a least a portion of the short leads, wherein the encapsulant is filled in the recesses.

2. The lead-frame type semiconductor package of claim 1, wherein a plurality of flow passages for an encapsulant flow are formed by the recesses.

3. The lead-frame type semiconductor package of claim 2, wherein the encapsulant flow is flowed into gap spaces between the long leads via the recesses.

4. The lead-frame type semiconductor package of claim 1, wherein the recesses are formed by half-etching process.

5. The lead-frame type semiconductor package of claim 1, wherein a width of each of the recesses is smaller than a width of the chip-attaching area.

6. The lead-frame type semiconductor package of claim 1, wherein a depth of each of the recesses is preferably half a thickness of each of the long leads.

7. The lead-frame type semiconductor package of claim 1, wherein gap spaces between the long leads are filled with the encapsulant.

8. The lead-frame type semiconductor package of claim 1, wherein both upper and lower surfaces of the long leads have the chips mounted thereon.

9. A lead frame comprising:
a lead frame body;
a plurality of short leads connected to the lead frame body; and
a plurality of long leads connected to the lead frame body and having a chip-attaching area predetermined thereon, wherein at least a portion of each of the long leads within the chip-attaching area is formed with a recess.

10. The lead frame of claim 9, wherein a plurality of flow passages for an encapsulant flow are formed by the recesses.

11. The lead frame of claim 9, wherein the encapsulant flow is flowed into gap spaces between the long leads via the recesses.

12. The lead frame of claim 9, wherein the recesses are formed by half-etching process.

13. The lead frame of claim 9, wherein a width of each of the recesses is smaller than a width of the chip-attaching area.

14. The lead frame of claim 9, wherein a depth of each of the recesses is preferably half a thickness of each of the long leads.
